(19) United States
(12) Patent Application Publication
(10) Pub. No.: US 2011/0290304 A1
(43) Pub. Date: Dec. 1, 2011

(54) PHOTOVOLTAIC MODULES ON A TEXTILE SUBSTRATE

(75) Inventor: JURGEN H. DANIEL, SAN FRANCISCO, CA (US)

(73) Assignee: PALO ALTO RESEARCH CENTER INCORPORATED, PALO ALTO, CA (US)

(21) Appl. No.: 12/789,291

(22) Filed: May 27, 2010

(51) Int. Cl. H01L 31/048; H01L 31/18; H01L 31/042

(52) U.S. Cl. 136/251; 136/244; 438/66; 257/E31.11

(57) ABSTRACT

A photovoltaic module having a textile substrate having conductors, an array of functional tiles on the substrate, wherein the functional tiles include solar tiles, the functional tiles arranged to be spaced apart from each other and to contact at least one conductor, and the solar tiles electrically connect in one of either electrical series or parallel configuration to produce and electrical power output. A method of manufacturing flexible, photovoltaic modules includes manufacturing at least one functional material, forming the functional material into functional tiles, mounting the functional tiles onto a textile substrate into an array of functional tiles, and forming circuitry on the flexible substrate to electrically connect the functional tiles to one of either input/output circuitry or other tiles.

### RELATED APPLICATION

This application is related to copending U.S. application Ser. No. ______ (Attorney Docket No. 20090641-US-NP-9841-0176) “Flexible Tiled Photovoltaic Module” filed May 27, 2010.

### BACKGROUND

Flexible photovoltaic modules may reside on flexible substrates such as thin, stainless steel foil or thin, polymer foil combined with thin photovoltaic (PV) films such as amorphous silicon, CIGS (Copper Indium Gallium Selenide) or organic semiconductors. These PV modules may be produced as rolls or sheets of flexible material with the solar cells or modules on the surface. This newly available format allows for much more flexibility in the layout and design of PV panels. However, even these more flexible PV panels have their limitations, including that the entire sheet or flexible panel must be of the same material and solar technology.

Different materials and technologies result in solar cells having different performance levels and price points. Typically ‘high’ performance solar cells consist of cells of III-V based materials. The term “III-V” refers to the groups on the periodic table. Group III materials include boron, aluminum, gallium, indium, thallium, and Group V materials include nitrogen, phosphorous, arsenic, antimony, bismuth. A III-V material, as that term is used here, is a material that is a compound of these elements, such as gallium arsenide (GaAs). The high performance solar cells generally have a higher power output for a given amount of sunlight than other available cells. Lower performing cells will generally have lower costs, being manufactured from more commonly-used materials such as silicon. The flexible substrates mentioned above must all be of the same type of solar technology and materials, and have further limitations as to the actual amount of flexibility provided in the material.

The availability of solar cells on the flexible substrates offers previously unavailable opportunities for solar cells across the range of performance levels.

### BRIEF DESCRIPTION OF THE DRAWINGS

FIGS. 1-3 show an embodiment of a method of manufacturing flexible photovoltaic modules using photovoltaic tiles.

FIG. 4 shows one embodiments of photovoltaic tiles on a flexible substrate.

FIG. 5 shows embodiments of mixtures of photovoltaic tiles on a flexible substrate.

FIG. 6 shows embodiments of alternative shapes of photovoltaic tiles.

FIGS. 7-10 show a process for manufacturing and connection of front contact photovoltaic tiles.

FIG. 11 shows an embodiment of a wiring diagram used to connect photovoltaic tiles.

FIG. 12 shows an alternative embodiment of a wiring diagram used to connect photovoltaic tiles.

FIG. 13 shows an embodiment of a drawn wire used to connect photovoltaic tiles.

FIG. 14 shows an embodiment of a system to print connections for photovoltaic tiles.

FIGS. 15-17 show an embodiment of a method of manufacturing and connecting back contact photovoltaic tiles.

FIG. 18 shows an embodiment of a double-sided substrate having back contact photovoltaic tiles.

FIG. 19 shows an embodiment of photovoltaic tiles with front contacts on a flexible substrate.

FIG. 20 shows an embodiment of solar tiles mounted on a textile substrate.

FIG. 21 shows a side view of an embodiment of solar tiles mounted on a textile substrate.

### DETAILED DESCRIPTION OF THE EMBODIMENTS

Currently, flexible, photovoltaic (PV) modules may be manufactured on flexible substrates such as thin stainless steel or polymer foil combined with thin PV films such as amorphous silicon, copper-indium-gallium-selenide (CIGS) or organic semiconductors. These modules are ‘monolithic’ in that they are manufactured such that they use the flexible substrate as their base layer essentially covering all of it with subsequent layers. The resulting PV modules may not have flexibility in all axes, although they generally are flexible or bendable around one axis.

Further, the materials used to fabricate flexible thin-film photovoltaic cells have less than optimal photovoltaic conversion efficiency. This reduces the usefulness of the modules, and it increases the area coverage required for reaching a particular power output.

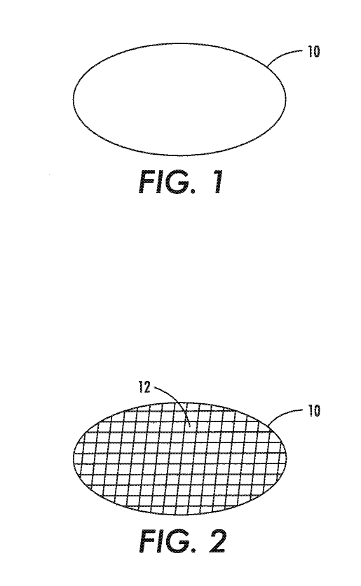

In addition to allowing use of the higher performance and higher conversion efficiency solar cells for flexible module integration, embodiments disclosed here allow for mixing different photovoltaic performance levels to allow for balance between cost and performance. Rather than manufacturing only one type of PV modules with these flexible substrates, however, it is possible to mix different types of PV cells onto one substrate during manufacturing. FIGS. 1-3 show a method of manufacturing PV modules using a flexible substrate.

FIG. 1 shows a typical, higher performance solar cell wafer such as a crystalline, single or multicrystalline, silicon wafer or a III-V material-based solar wafer. Higher performance solar cells are generally more efficient than the before mentioned thin-film solar cells, producing more power per area and per units of illumination. Generally, solar cells manufactured from groups III and V materials on the periodic table, referred to here as III-V compounds, have shown the greatest solar efficiency with values above 40% for multi junction cells, but their cost is generally high. Other high-performance cells fabricated at lower cost may consist of silicon, such as crystalline silicon, and those cells have achieved efficiencies above 24%.

The described high-performance cells are based on wafers which are typically rigid and not flexible unless they are very thin. In order to obtain flexible solar modules from these ‘rigid’ cells, the cells are divided into solar ‘tiles’ or solar ‘flakes’. However, the concept of ‘tiling’ is not limited to rigid cells. Thin silicon, such as for example 5-100 micron thin silicon sheets or wafers, is rather flexible and it may be cut into tiles/flakes. This is also the case with other thin-film based photovoltaic technologies, which may be cut into small tiles as well.

For example, flexible III-V cells on stainless steel foil with high efficiency have been demonstrated. Also, chalcogenide material such as Cu (In, Ga) Se2 or CIGS may be deposited on glass or stainless steel foil. Other materials may be used such as CdTe, amorphous silicon, nanocrystalline silicon, organic semiconducting material, nanowire or nanoribbon based solar material or dye-sensitized photovoltaic material, for example.

FIG. 2 shows a solar wafer 10 which is divided into individual PV module flakes or tiles such as 12. The division into these flakes may occur by a cutting or dicing process, including sawing, laser-cutting, water-jet cutting, sand/bead blasting, mechanical breaking, etc. The individual flakes or tiles may have a variety of shapes and may range for this application in size from millimeter-size to several centimeters. In particular, the solar tiles may have a minimum lateral dimension of 5 millimeters and a maximum lateral dimension of 10 centimeters. In a more narrow range the tiles have a minimum lateral dimension of 1 cm and a maximum lateral dimension of 5 cm.

The thickness of the tiles depends on the solar cell technology and typically may range from a few microns to several millimeters. For example, the tiles may be 1 cm by 1 cm square or for a finer tiling grid they may be 5 mm by 5 mm. Smaller tiles often have slightly reduced solar efficiency because of edge effects, therefore a balance between the desired bending radius and the solar efficiency of the flexible modules has to be achieved. The dicing or cutting process may be followed by an etch process such as a wet-etch to remove defects in the material. Defects may otherwise cause propagating cracks or charge-carrier recombination and therefore decreased performance of the individual tiles or flakes.

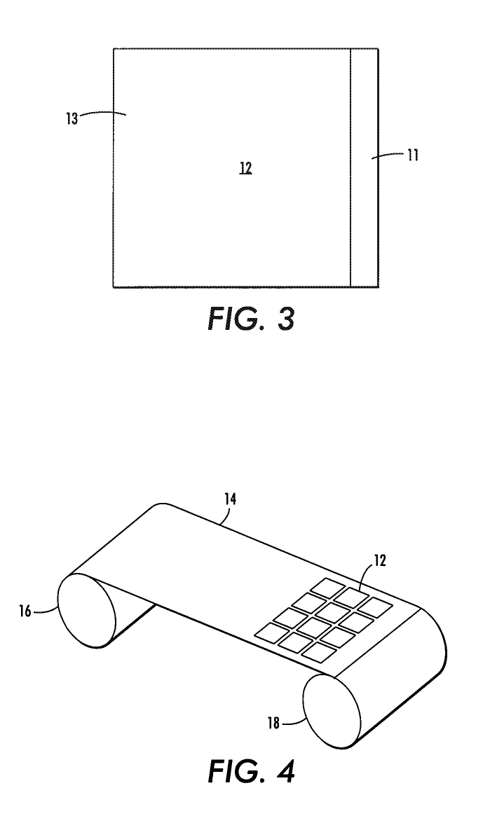

FIG. 3 shows an individual tile 12. As mentioned above, different types of tiles may consist of different solar materials. Additionally, the solar tiles may also consist of luminescent material with an attached photovoltaic cell, which would be another type of a solar tile. For example, each tile may consist of a transparent material such as glass or plexiglass, acrylic, with embedded or surface-coated fluorescent dye or fluorescent pigment in region 13. In one example, fluorescent size-tunable nanocrystals such as CdSe nanocrystals may be applied, either to the surface of the transparent tile or they may be embedded in the material. Other fluorescent materials used in the fluorescent concentrator tile include PbSe quantum dots, rare-earth based upconverting materials, perylene, 4-(dicyanomethylene)-2-t-butyl-6-(1,1,7,7-tetramethyljulolidyl-9-enyl)-4H-pyran (DCJTB), rubrene, trans-thioindigo, for example. The fluorescent tile may have a size of 3 cm by 3 cm and a thickness of 1 mm, for example. However, smaller or larger size tiles are also possible.

At the edge, a strip of a solar cell 11 may be attached to convert the collected edge emitting fluorescent light into electricity. The other sides or edges of the fluorescent tile may be coated with a reflective mirror layer to prevent light form coupling out of the tile. The solar cell strip may also be attached to the front or back surface of the fluorescent tile, such as with index-matching material such as a silicone polymer. In this case, all of the sides of the fluorescent tile should have a reflective mirror finish. This reflective finish may be applied by evaporation or by printing of a reflective substance such as aluminum or silver ink. The solar cell strip may be a back contact cell in which case the assembly of the fluorescent tile to the cell does not interfere with contacts on the front cell surface. In this embodiment, the solar cell strip may be several millimeters to centimeters long and only a few millimeters wide. In one example the solar cell strips may be Sliver® cells by Origin Energy Solar Pty, Ltd. of Regency Park, South Australia.

The individual tiles or flakes 12 can then be mounted onto a flexible substrate 14 shown in FIG. 4, possibly in a roll to roll process, where the flexible substrate is for example mounted on rollers 16 and 18. The flexible substrate may consist of a flexible polymer which may be transparent or partially transparent to visible, light, ultraviolet light or infrared light. However, the flexible substrate may also consist of an opaque material such as stainless steel foil, titanium foil or aluminum foil or a combination of metal and polymer. Examples of flexible polymer substrate materials are Mylar™, Kapton™, polyethylene naphthalate, polyethylene terephthalate, Tedlar™, Teonex®, Melinex®, Araldite® polycarbonate, and others. The flexible substrate may also consist of ceramics such as ZircoFlex™ or composites such as ceramic-polymer composites.

The flexible substrate may also consist of a fabric or textile, in particular a woven textile. These woven materials will be referred to here as ‘textiles.’ In particular, the flexible substrate may consist of a textile that possesses high tensile strength which renders the textile ‘bullet proof’. Examples of textile materials are Kevlar, Nylon, carbon fiber, polyester, aramid, glass fibers, PTFE fiber, temperature resistant silica textiles such as Siltex®, liquid crystal polymer fiber based materials such as Vectran®, ceramic fiber based materials such as Nextel™, Rayon and other synthetic and natural fiber materials.

The thickness of the flexible substrate may vary depending on the rigidity of the material and it may be as thin as a few microns and as thick as a few millimeters. However, the flexible substrate should have preferably a bending radius of less than 5 cm and more preferably less than 2 cm. A lower bending radius indicates a more flexible material.

As the web or roll passes a pick and place station, the tiles are placed on the substrate and then the substrate with the tiles on it is taken up by the roller 18. This method is made possible by the flexibility of the substrate, and allows for high speed manufacture of flexible PV modules. However, the described concept is not limited to roll-to-roll processes and batch processing may also be employed to transfer the solar ‘flakes’ or ‘tiles’ onto a substrate. In a particular case, the substrate may not be flexible or a flexible substrate may be temporarily mounted to a rigid carrier during the processing. Example processes for the placement of the tiles include pick and place methods such as those performed by machines from Muehlbauer Holding AG (Roding, Germany). Placement may also occur with parallel processes such as the transfer printing processes by Semprius, Inc. (Durham, N.C.).

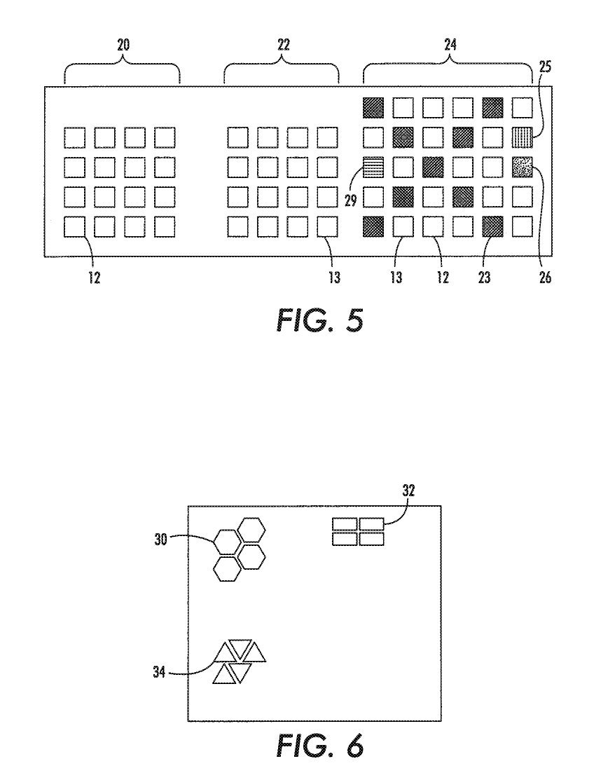

Using such a process, one could mix and match different types of PV tiles onto the substrate. For example, FIG. 5 shows a first array of PV tiles 20 in which all of the tiles in the array are high performance and more expensive PV tiles, from III-V material for example. The array 20 provides high performance and high efficiency, but also has higher cost. In contrast, the array of tiles 22 consist of lower performing tiles that have lower cost, such as silicon tiles of single or multicrystalline silicon. One can strike a balance between the cost and performance by mixing the two types of tiles as shown in the hybrid array 24, which is a mix of high performance tiles such as 12 and low performance tiles such as 13.

Referring to the roll to roll process above, one could imagine that one type of tile could be placed on the substrate during the roll to roll process and then the gaps filled with the second type of tile during another roll to roll process or by other manufacturing techniques. As can be seen, in this approach, the individual solar tiles may originate from a range of solar technologies, including rigid, semi-rigid or flexible cell materials.

Also, in this approach, not all of the tiles need to be solar cell tiles. In order to create a solar blanket with greater functionality, a solar tile in the array may be left out or replaced with an element that has a different function. Array 24 of FIG. 5 may also be a combination of tiles, rather than a mix of different types of solar tiles 12 and 13

For example, leaving out a solar tile and replacing it with a light source 29, such as a tile of electroluminescent material or a tile with a light emitting diode, would create a solar blanket that can also be used to illuminate an area at night. In this case, the power for the embedded light sources may originate from the photovoltaic blanket and a power storage unit.

The power storage unit may be also in the form of a tile 25. For example, a solar tile may be replaced by a thin battery or charge storage unit, such a thin film battery, capacitor or supercapacitor. Of course, the charge storage unit may be also attached directly to the underside of the solar tiles. A solar tile may be also replaced by other electronic units, such as light monitoring or sensor units 26 as well as power regulating units. For example, a tile may consist of a micro-converter to convert the DC voltage of neighboring solar tiles into an AC voltage. A sensor such as a photodiode may be integrated into a tile to monitor illumination.

Other sensors may be embedded into the solar blanked on the tiles, such as accelerometers, pressure sensors, motion sensors, moisture sensors, gas sensors, radiation sensors and biological or chemical sensors. In general, this combination of solar tiles with tiles that have a different function would make the solar blanket multifunctional for environmental monitoring or in military environments. Also, a tile may display a color in form of an emissive or reflective display. For example, a tile may be a display such as an electrophoretic display, electrochromic display, liquid crystal display, MEMS interference display, electrowetting display, powder display, electrochemical display, organic or inorganic light emitting display, plasma display. Several display tiles distributed over the solar blanket may display an information message, a picture or they may be used for camouflage or aesthetic purposes in order to adjust the color or appearance of the solar blanket to the environment. This is shown in FIG. 5 by display tiles such as 23 forming the letter ‘X’ on the surface of the flexible substrate.

Because the tiles may have one of several different functions, the manufacturing process will refer to as manufacturing ‘functional material.’ For example, the functional material from which solar tiles arise would be solar cells; the functional material from which sensors come may be an array or other portion of sensors. The functional material is the source of the tiles, whether those tiles are solar tiles, sensors, display tiles, etc.

Other considerations than cost and performance may factor into the desire for a hybrid array of two or more types of tiles. For example, one region of a module may be populated with silicon-base solar tiles having a band gap of 1.1 eV, and another with CICS solar tiles having a band gap of 1.6 eV. If the module resided on the wing of an airplane or UAV flying at high altitude, the front surface may require modules that have a high absorption of long wavelength light and the back surface may require higher absorption of shorter wavelength light. By manufacturing substrates with mixed PV modules, both of these needs can be met. This approach of tiling the modules allows for rapid changes and flexibility in manufacturing and applications.

In addition to flexibility in the mixes of tiles used, the tiles may have different shapes. The shape results from the manufacture of the solar tiles from the wafers, referring back to FIGS. 1-4. A solar ‘cell’ means the entity before dicing into ‘flakes’ or ‘tiles.’ The solar tiles may take different shapes, as shown in FIG. 6. Examples shown here include hexagonal tiles such as 30, rectangular tiles such as 32, and triangular tiles such as 34, in addition to the square tiles shown in FIG. 5. Other shapes, such as octagonal, pentagonal, oval, round, etc. are of course possible, limited only by the manufacturing capabilities.

The spacing between the tiles may depend on the required bending radius and on the application. Depending on the thickness of the tiles, larger gaps may allow a tighter bending radius. For example, at a tile size of 5 mm, a gap of at least 0.02 mm is required for 200 micron thick cells if a bending radius of 50 mm is desired. If the cell thickness is reduced to 50 microns, a gap of only at least 0.005 mm is required to achieve the same bending radius. Larger gaps may also allow more light to shine through the solar module or solar blanket if the substrate is transparent. Therefore, the tiles may be spaced further apart if light illumination of the space underneath the solar module is desirable. For example, if the solar blanket is used instead of the canvas for a tent, a certain amount of light transmission may be desirable to illuminate the inside of the tent. The spacing between tiles may be the same for all tiles or it may be different for different sides of the tiles. The wider the spacing between tiles, the smaller the solar cell fill factor and the lower the solar efficiency of the module per area. A module made with 1 cm tiles spaced at 500 microns has a fill factor of ˜90%. This fill factor decreases to ˜83% if the gap is increased to 1 mm.

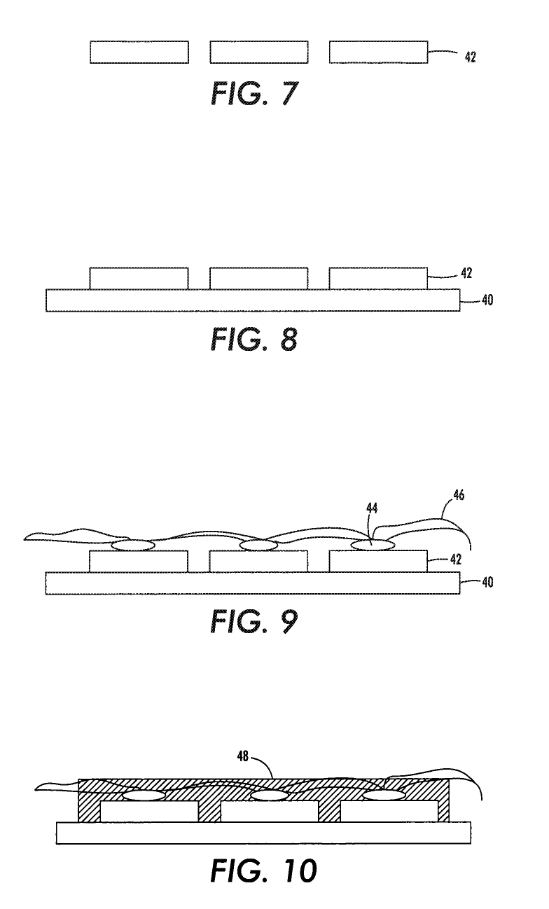

The solar tiles may have front contacts or back contacts, where a front contact cell typically has front and back contacts for connections. A typical solar cell has a front contact and a back contact between which the photovoltage is measured. A back contact cell, such as those manufactured by Sunpower, Inc., or others fabricated with an emitter wrap-through or emitter wrap-around technology has all contacts located on one side of the cell, typically the back. Back contact cells have the advantage that there is less or no shading from the contacts and gridlines on the cell surface. Also, mounting of the cells in module assembly can be simpler because connections have to be established only on one side of the cells. For tiles with back-contact configuration, the mounting of the tiles to the substrate could occur in a manner similar to flip-chip mounted integrated circuits, with solder balls or other connection on the substrate to which the tile contacts are connected. FIGS. 7-10 shows an embodiment of a manufacturing process for solar tiles with contact on the front and back side.

In FIG. 7, solar tiles 42 are shown. In FIG. 8, the solar tiles are attached to a flexible substrate 40. The substrate may be a conductive substrate such as Metal Rubber™, developed by Virginia Tech and NanoSonic, Inc., or stainless steel foil or metalized plastic foil, as examples. In that case, the back contacts of the tiles are electrically connected. The attachment of the tiles to the substrate may occur via solder or conductive adhesive such as silver-filled epoxy or silver-filled elastomer. These solar tiles are front-contact, so there may or may not be any circuitry on the substrate 40, as will be discussed in more detail later. However, the substrate itself is conductive, so it will generally act as the lower electrode, with the wiring and circuitry being on the front surface of the cells. The contacts on the fronts of the solar tiles 42 receive a contacting compound 44 such as a conductive epoxy or solder in FIG. 9.

Wires such as 46 in FIG. 8 provide connection between the tiles and to any circuitry. In the case of FIG. 9, the solar tiles would be all connected electrically in parallel. The wires may be placed on the tiles first and then fixed into place with the contacting compound 44, or the contacting compound may be provided first with the wires connected later. In either case, the wires provide connection between the solar tiles. The wires or connections may also be printed by known printing techniques such as extrusion, screen printing, inkjet printing, flexography, for example.

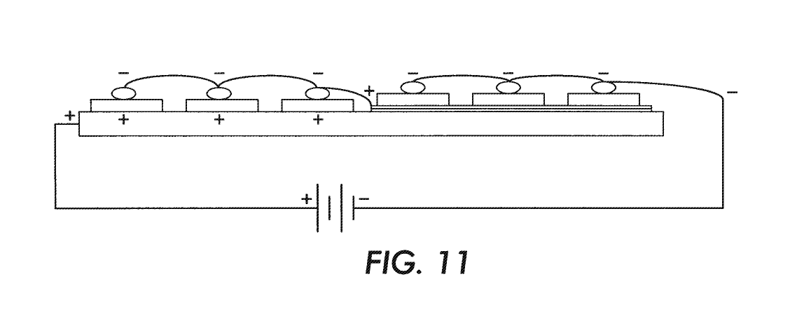

While the embodiment here shows the wiring as being on the front contact of the solar cell, some of the wiring may reside near or on the substrate as well, with appropriate insulators to isolate the wiring or circuitry from the conductive substrate. This way, arrays of parallel connected tiles may be connected in series in order to increase the voltage of the solar module. Particularly, as shown in FIG. 11, arrays of tiles may be connected in parallel and in series. An additional insulating layer with metallization, applied for example by a printing method, has to be included on the substrate. The insulating layer may also be laminated and aluminized Mylar foil or copper coated Kapton foil are examples of layers that may be laminated onto the substrate with double sided pressure sensitive adhesive tape.

In order to secure the wires and the tiles to the substrate, an encapsulating compound 48 may enclose the tiles, the contacting compound and portions of the wires as shown in FIG. 10. Generally, the compound will consist of an elastomer, to allow the resulting structure to be flexible. Using an elastomer also allows the structure to stretch, rather than just to flex.

Laminated ethylene-vinyl-acetate (EVA) may be one example of an encapsulant. Liquid encapsulants such as the PV-6100 series or PV-6010 from Dow Corning or silicones, fluorosilicones, acrylics and urethanes are other examples.

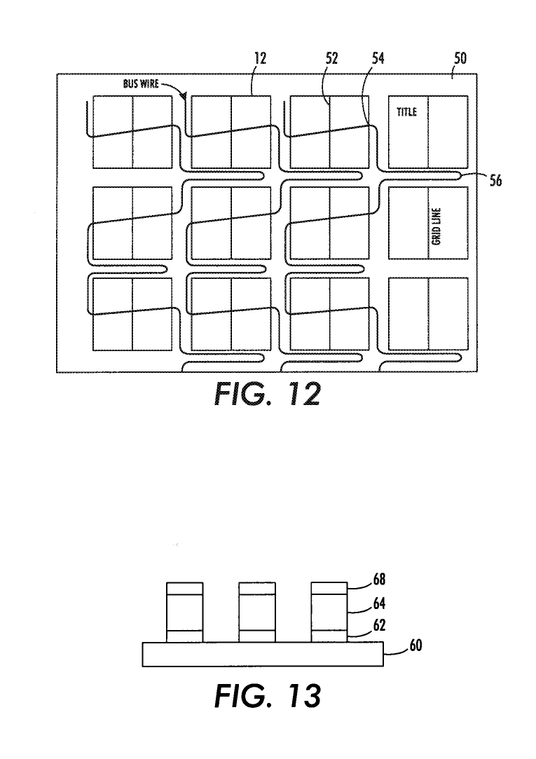

FIG. 12 shows an example of a routing diagram for front contact solar tiles, building on the idea of front contact solar tiles of FIGS. 7-10. The tiles such as 12 reside on a flexible substrate 50. The tiles may have grid lines such as 52 that are connected together by bus lines such as 54. In order to ensure that the wiring allows for maximum flexibility, the wires may have loops such as 56. The loops allow the wires to flex and have slack so as to not interfere with the flexibility of the overall module. The substrate may be conductive or it may have conductive traces such as copper or silver traces patterned on it so that the back contact of the cells makes electrical contact. The tiles may be soldered or glued with conductive adhesive to the conductors on the substrate.

In a further embodiment, at least part of the connection may consist of wires coated with low melting point solder, such as those used by Day 4Energy, Inc. In that case the wires may be soldered to the gridlines 52. Further, the slack wires may route in the gaps between the tiles to avoid ‘shading loss’ where portions of the solar tiles do not receive light because they would lay in the shade of the wires.

The wires may also consist of ‘drawn wires’ in which the process prints a seed layer, as shown in FIG. 13. The seed layer may be printed, evaporated through a shadow mask, or deposited by a laser transfer or activation process. In FIG. 13, the seed layer 62 undergoes a plating process of a good conductor such as copper 64. The nature of solar modules requires that the connections carry relatively high currents, and low resistance is desirable. The plating step using a good conductor lowers the resistance while increasing the current carrying capacity of the conductors. The described seed layer may be a catalyst such as a palladium colloid for electroless plating or it may be a printed layer of silver, for example. The seed layer may be also a sputtered or evaporated layer of other seed metal or seed material such as copper, silver, gold, nickel, etc., to enable electroplating, for example.

The conductor 64 plated onto the seed layer 62 may then receive a coating of tin or low-melting point solder 68. Using printing to pattern the bus lines, the routing for the individual tiles may easily change. This may have particular advantages when different cell technologies reside on the same substrate. The base layer 60 may be the solar cell surface or the material in between the cells. The material in between the cells may be a deposited insulating material such as an elastomer material including silicones, acrylics and urethanes. A protective encapsulation layer such as EVA may then be laminated or liquid polymers such as fluorosilicones, etc. may be coated on top. The printing of connection layers may occur before or after the mounting of the front contact solar tiles upon which the discussion has focused so far.

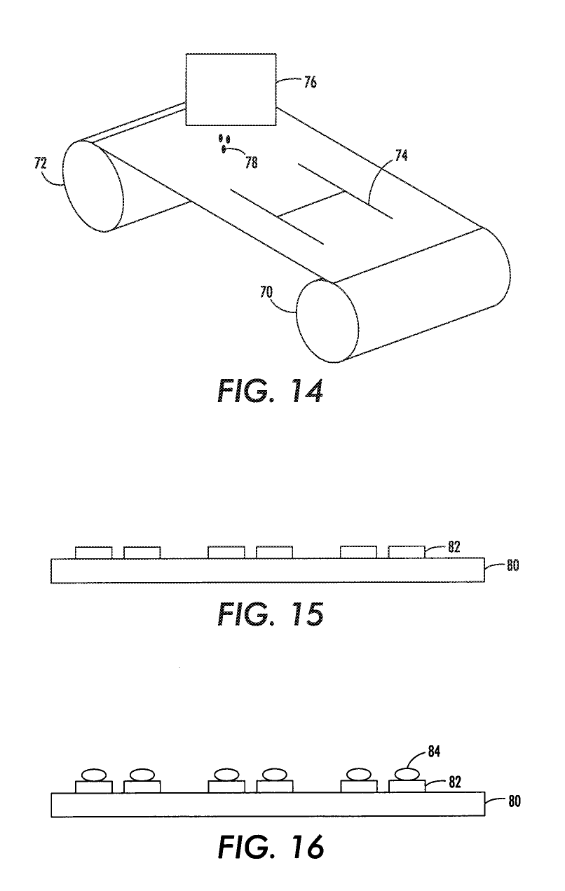

Since these kinds of cells require connections on both sides of the cell surface, the described printing process may be applied for forming the connections to the back contact of the cells as well as to the front contact of the cells. Printing may also form connections between the front and the back contacts of neighboring cells. For back contact solar tiles, the printing of the circuitry and contacts or connections will more than likely occur prior to the mounting of the solar tiles. As mentioned before, this process would appear similar to flip-chip mounting of integrated circuits in which contact pads reside on a circuit substrate such as a printed circuit board (PCB) to which the integrated circuit dies connect after formation of the contact pads. FIGS. 14-18 show embodiments of such a process.

In FIG. 14 the circuitry and contact pads for the solar tiles are formed on a flexible substrate. Generally, the substrate here will not be conductive. In the example of FIG. 14, the relevant circuitry are printed or otherwise deposited onto a flexible substrate in a roll-to-roll process with rollers 70 and 72. As mentioned previously, the high current carrying capacity and desirably low resistance of conductive paths in a solar module may require plating after depositing of the initial layer.

In the embodiment of FIG. 14, a print head 76 dispenses conductive material 78 in a particular pattern to form the circuit traces 74. The print head 76 may be an inkjet printhead, an aerosol printhead, a screen printing unit such as a rotoscreenprinting unit, a flexography, gravure, offset printing unit, extrusion printer or other printhead system. The print head 76 may also include other deposition systems such as a laser or thermal transfer printhead or a laser, electron-beam or ion beam deposition unit. Moreover, it may be a direct-write dip-pen dispensing system or a nozzle-based dispensing or extrusion system.

However formed, the contacts and conductive traces 82 reside on the flexible substrate 80 shown in FIG. 15. The conductive traces may also be formed by ‘digital printing’ in which printing of a masking polymer such as a wax is used to deposit locally an etch mask. The underlying metal layer is then etched using generally known etching methods and the areas which are protected by the printed masking layers remain. Apart from conductive traces, the ‘printing process’ may also attach circuit elements such as bypass diodes, resistors, electric fuses or microinverters to the substrates. These circuit elements may be printed in the form of a solution such as by depositing organic diodes, or they may be attached by a pick and place method or by a transfer printing process, for example by a process similar to the micro-transfer printing process by Semprius, Inc. of Durham, N.C. This particular sequence discusses the mounting of the solar tiles, with the understanding that many of the circuit elements will reside on the substrate 80 just as the contact pads 82 reside there.

As mentioned above, specific circuit elements that may be of interest include bypass diodes, fuses and microinverters. In order to prevent shading loss and to reduce loss due to damage to the solar module such as by puncture, bypass diodes may be integrated onto the module in a distributed fashion. Printing and patterning techniques allow these elements to reside in several places on the flexible substrate and can relocate within the pattern as needed. For example, bypass diodes may consist of Schottky diodes and they also may include printed organic or inorganic diodes.

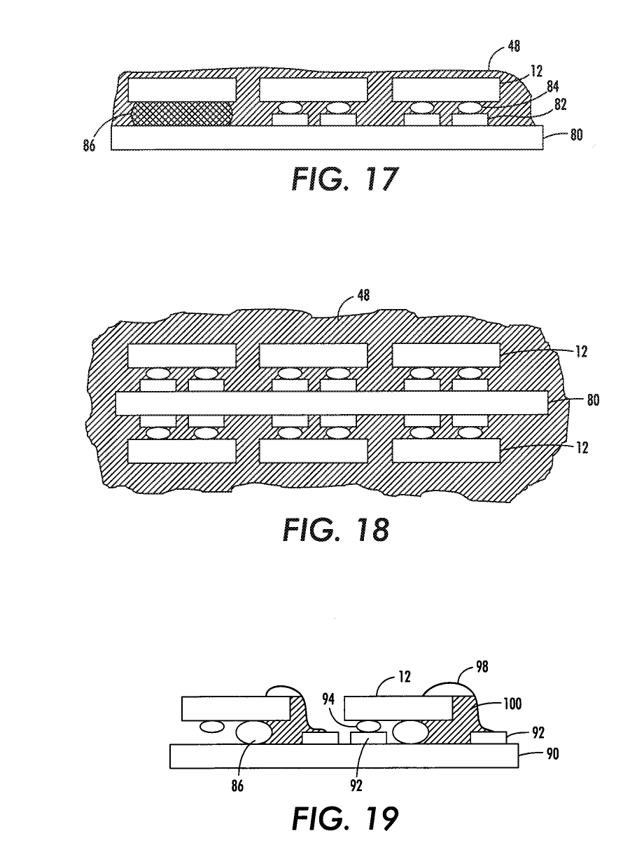

In FIG. 16, a contacting compound 84 such as solder or conductive epoxy as examples is deposited onto the contacts 82. The deposition may occur by a printing method, a plating method or other deposition method. The solar tiles such as 12 are then mounted onto the contacting compound on the contact pads as shown in FIG. 17. In a further modification, solar tiles could be mounted on both sides of the substrate 80 as shown in FIG. 18.

FIGS. 17 and 18 show back contact solar cell tiles in which the photocurrent is extracted via the two contacts at the back of the cell. Between the two contacts, the photovoltage of a cell can be measured. By connecting tiles in series, the resulting voltage is increased and the current through all the cells is the same. By connecting the tiles in parallel, the total voltage is the same but the resulting current is higher.

It is important that the contact resistance between the cell tiles and the conductive traces on the substrate is low. The contacting material 84 shown in FIG. 17 may be a lead-tin solder or other solder material which melts upon heating or it may be a conductive adhesive such as silver epoxy, including elastomeric silver adhesive. The adhesive may be also an anisotropic conductive adhesive in order to prevent lateral shorts. ACF adhesive 7313 from 3M is an example of a thermoplastic adhesive mix randomly loaded with conductive particles. The anisotropic adhesive may also be applied in form of a tape. In this case, the tape may be laminated as a continuous layer without patterning it. Other application methods for liquid based adhesive include printing or nozzle dispensing. An example of electrically conductive epoxy adhesive is ECA adhesive from Intek Adhesives, Ltd. or 40-3900 electrically conductive resin from Epoxies, Etc. (of Cranston, R.I.).

The arrangement of FIG. 18 may enable light capture from both sides of the solar blanket. Ideally, the tiles on both sides are aligned to each other so that a common gap between the cell tiles remains. This common gap ensures flexibility of the solar blanket. In a specific example, the solar tiles on one side are smaller than on the other side or they may be distributed sparsely. The tiles in FIGS. 17 and 18 may also have an underfill material, such as 86 in FIG. 17, that improves the adhesion of the cells to the substrate and that may conduct heat away from the cell. Loctite 3508 (from Henkel) is an example of an epoxy-based underfill material. The underfill may be an elastomeric material such as a silicone or an acrylic. The tiles may also be encapsulated by a layer 48 in FIGS. 17 and 18. This may occur by laminating a material such as EVA (ethylene-vinyl acetate) over the tiles. EVA is reasonably elastic so that the entire module retains its multi-axis flexibility. Also, a liquid encapsulant may be applied such as Dow Corning PV-6100 series or PV-6010 silicone cell encapsulant or other silicones or fluorinated silicones.

The layer 48 may also have anti-reflective properties to improve the light capture of the solar module. The layer may also have properties that repel dust and other surface deposits. The layer 48 may also provide scratch resistance and therefore include a hardcoat material such as silica particles in a polymer. Moreover, the layer 48 may consist of a stack of layers. Therefore, the layer 48 may contain fluorocarbon compounds, nanoparticles or it may contain anti-reflective components such as the coating from XeroCoat, Inc. (Redwood City, Calif.).

FIG. 19 shows another alternative solar tile configuration. The solar tile 12 in FIG. 19 which is a ‘front-contact’ solar cell has both back and front contacts. The photovoltage of such cells is measured between the front and the back contact. In this embodiment, the solar tile 12 has a back contact that connects via solder or other contacting compound 94 to contact pad 92 on flexible substrate 90. In addition, bus line 98 connects to the front of solar tile 12 and then to a contact pad 92 on the substrate 90. The bus lines such as 98 may be formed by a printing method. A printed, molded or otherwise deposited insulator 100 provides protection and electrical isolation for the contact pad 92 and the underside of the solar tile in the region near that contact pad. The insulator may be an epoxy compound, an acrylic, a silicone, polystyrene or polyimide, for example. Alternatively, the insulating layer 100 may not be required if the solar tiles have an insulation layer that prevents shorting of the front and back contacts when depositing the connection 98. The material 86 may be an adhesive that attaches the tile to the substrate. It may be an epoxy or silicone compound, for example and it may possess good thermal conductivity to transport heat from the tile to the substrate. The tiles shown in FIG. 19 may also be encapsulated with a protective layer such as layer 48 shown in FIGS. 17 and 18.

The conductor may consist of a bonded wire or a printed conductor. For example, the conductor may be printed by an aerosol printer such as by Optomec followed by a plating step to increase the conductivity. Other printing methods such as for example transfer printing, screen printing, inkjet printing or flexography may also be applied. The insulator 100 may also be uniformly applied over the surface by a laminating method such as laminated EVA or by a blading or dispensing method such as extrusion. Then via holes may be drilled, for example by a laser process, to access the contact area on the solar tile and on the conducting line 92. The connection 98 may be printed over the insulator between the laser-drilled vias. Instead of printing, other methods such as wire bonding may also be used to form the connections.

In a specific embodiment, the described solar module is based on a textile substrate such as a woven fabric. Textiles have high flexibility or even stretchability in multiple axes because they consist of woven fibers or other networks of fibers. The fibers may consist of a natural material such as cotton or of a synthetic material such as Nylon or Kevlar, for example. Conductive fibers have been also woven into textiles in order to provide a fabric that can conduct electricity. These fibers may be metalized polymer fibers or metal wires. For example, the conducting fibers may be nylon fibers which have been coated by electro or electroless plating with nickel or copper. Electrical conductivity of textiles can also be achieve by sewing conductive wires into the fabric, by gluing conductive wires or conductive traces to the fabric such as by hot-melt glue, by printing conductive traces onto the fabric such as by screen printing of silver paste, by transfer printing, such as thermal transfer, of conductive traces, or by metalizing the fabric via physical or electrochemical plating methods and then selectively etching away the metallization. The conductive traces may also consist of conductive carbon fiber. The entire substrate may consist of conductive fiber such as woven conductive carbon fiber fabric, for example manufactured by Sigmatex High Technology Rabrics, Inc., of Benicia, Calif. Other metallization methods generally known may be used as well. These conductive fibers, traces and metallization will be referred to here as ‘conductors.’

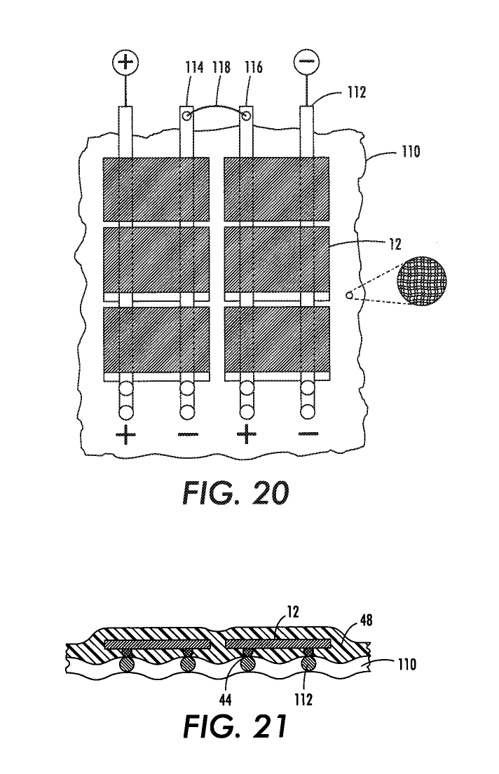

Recently, it has been shown that textiles can also be rendered electrically conductive by dipping them into a solution of carbon nanowires. Electrically conductive coatings may include metals such as copper, gold, nickel, silver, etc. or it may include organic conductors such as PEDOT:PSS or carbon nanotubes or graphene. The solar or functional tiles may be attached to the fabric as described above and the conducting traces in or on the woven fabric will transport the electricity to the edges of the module. In particular, the tiles may be attached in a manner similar to flip-chip attachment of integrated circuits in which the contacts are on the bottom surface of the tiles. The textile substrate with the solar tiles may then be sealed or encapsulated as described before with a liquid encapsulant, such as a silicone resin, or by using laminated EVA or similar material. Due to the highly flexible nature of textile substrates, encapsulants that have elastomeric properties are particularly useful. Silicones, fluorinated silicones, polyurethanes or acrylic elastomers are examples. Liquid encapsulants may be applied by a solution coating method and then be dried or otherwise cross linked or solidified. Encapsulants may also be evaporated and an example is Parylene, for example. FIGS. 20-21 show an illustration of this concept in which solar tiles with back contacts are attached to a woven fabric and the contacts of the tiles are connected to conductive fibers or wires that are sewn or woven into the fabric. The fibers or wires may then be connected to form series or parallel connections of tile strings.

FIG. 20 shows a top view of solar cells such as 12 on a woven fabric 110. The woven fabric 110 has conductive fibers or lines 112, 114 and 116. The solar cells are mounted on or electrically connected to these lines, the lines to conduct the electricity generated by the solar cells. In some embodiments, the lines in the fabric have alternating polarities, such as line 114 being negative and line 116 being positive, because of being connected to the respective electrodes of the solar tiles. The lines may be cross-connected as shown by wire, conductive fiber or printed conductor 118. This way, parallel and series connections of solar cell strings can be established in order to achieve a desired output voltage and current range of the flexible module.

FIG. 21 shows an embodiment using a woven fabric or textile substrate in a side view. As discussed previously, the functional tiles and the solar cells may undergo some sort of dicing or separation process that results in solar tiles or flakes or they may be manufactured out of some larger cell or functional material. The solar tiles such as 12 will reside on the fabric 110. Fabrics with embedded conductive wires are available, for example, from ‘Less EMF, Inc.’ An example of metalized fabric is Flectron® from Laird Technologies™. The metallization of metalized fabric may be patterned by photolithography and wet etching methods or by ‘digital lithography’ employing printing of a masking layer and wet etching of the unprotected regions. The cells are oriented and placed such that they contact the conductive lines or fibers such as 112.

The cells attach to the conductive lines using conductive adhesive, solder or other electrically conductive compound or material, such as 84 from FIG. 17 or 44 from FIG. 9. Examples of conductive adhesive are the thermoplastic pastes PSS8150 and PSS8159 from AIT Technology, Inc. as well as the flexible epoxies ESS8450, ESS8457 and ESS8459 from AIT Technologies, Inc. The conductive adhesive may be dispensed onto the woven fabric in many ways, many of which are mentioned above, including printing. The process places the cells on the conductive adhesive, which may or may not need to be cured. Once the cells are attached to the conductive fibers, they may be enclosed in the encapsulant 48. The encapsulant may be dispensed in many ways, as discussed above. Also, an underfill material may be applied before the encapsulation. Potential underfill materials are MEE7650-5 and MEE7655-5 from AIT Technologies, Inc. or the flip chip underfill materials from Namics Corporation, such as U8439-105 or U8439-1.

In this manner, a flexible, photovoltaic module is provided. The module has great physical flexibility allowing the substrate to flex in all axes of movement. In addition, the manufacturing process has great flexibility allowing designers to mix and match different types of solar modules to meet cost and performance goals, ensure receptivity to different wavelengths of light, and many others.

It will be appreciated that several of the above-disclosed and other features and functions, or alternatives thereof, may be desirably combined into many other different systems or applications. Also that various presently unforeseen or unanticipated alternatives, modifications, variations, or improvements therein may be subsequently made by those skilled in the art which are also intended to be encompassed by the following claims.

What is claimed is:

1. A photovoltaic module, comprising:
a textile substrate having conductors;
an array of functional tiles on the substrate, wherein the functional tiles include solar tiles, the functional tiles arranged to be spaced apart from each other and to contact at least one conductor; and
the solar tiles electrically connect in one of either electrical series or parallel configuration to produce and electrical power output.

2. The photovoltaic module of claim 1, wherein the array of solar tiles includes solar tiles that are portions of different types of solar cells.

3. The photovoltaic module of claim 2, wherein the different types of solar cells include at least one of solar cells made of III-V materials, silicon, chalcogenide, fluorescent concentrator, and organic semiconductors.

4. The photovoltaic module of claim 1, wherein the functional tiles include at least one of a battery, a display tile, a power regulator, and a sensor.

5. The photovoltaic module of claim 4, wherein the display tile comprises one of electrophoretic display, electrochromic display, liquid crystal display, MEMS interference display, electrowetting display, powder display, electrochemical display, organic or inorganic light emitting display, plasma display

6. The photovoltaic module of claim 4, wherein the sensor further comprises one of a photodiode, an accelerometer, a pressure sensor, a motion sensor, a moisture sensor, a gas sensor, a radiation sensor, a biological sensor, or a chemical sensor.

7. The photovoltaic module of claim 1, wherein further comprising an encapsulant around at least one of the solar tile and the textile substrate.

8. The photovoltaic module of claim 7, wherein the encapsulant comprises one of liquid encapsulant, laminated encapsulant, evaporated encapsulant, a silicone encapsulant, EVA, and Parylene.

9. The photovoltaic module of claim 1, wherein the conductors comprise one of conductive fibers woven into the textile, conductive fibers sewn into the textile, conductive fibers glued onto the textile, printed traces on a surface of the textile, and carbon nanowires attached to a surface of the textile.

10. The photovoltaic module of claim 1, further comprising one of a conductive adhesive and a solder material between the solar tile and at least one conductor.

11. The photovoltaic module of claim 1, wherein the solar tiles are arranged on either one side of the substrate or both sides of the textile substrate.

12. A method of manufacturing flexible, photovoltaic modules, comprising:
manufacturing at least one functional material;
forming the functional material into functional tiles;
mounting the functional tiles onto a textile substrate into an array of functional tiles; and
forming circuitry on the flexible substrate to electrically connect the functional tiles to one of either input/output circuitry or other tiles.

13. The method of claim 12, wherein manufacturing at least one solar cell comprises manufacturing a solar cell out of one of III-V materials, silicon, chalcogenide, fluorescent concentrator material and organic semiconductors.

14. The method of claim 13, wherein manufacturing at least one solar cell comprises manufacturing at least one solar cell each out of at least two of III-V materials, silicon, chalcogenide, fluorescent concentrator material and organic semiconductors, and mounting the solar tiles onto the textile substrate comprises mounting a mixture of the solar tiles from solar cells of different materials.

15. The method of claim 12, wherein forming the circuitry comprises one of: weaving conductive fibers into the textile; sewing conductive fibers into the textile; gluing conductive fibers to the textile, printing conductive traces on the textile; metalizing the textile and selectively removing the metallization; and dipping the textile into a solution of carbon nanowires.

16. The method of claim 12, further comprising encapsulating the textile substrate and the functional tiles.

17. The method of claim 16, wherein encapsulating the textile substrate comprises encapsulating the textile substrate and the functional tiles with one of a liquid encapsulant, an encapsulant laminated to the textile substrate and the functional tiles, and evaporating the encapsulant.

18. The method of claim 12, further comprising attaching the functional tiles to conductive fibers in the textile substrate using one of a conductive adhesive or solder.

19. The method of claim 12, wherein mounting the functional tiles comprises mounting the functional tiles to be connected electrically in one of either parallel or in series by the conductive fibers.

20. The method of claim 12, wherein forming the circuitry comprises arranging the conductive fibers in the textile substrate to route electricity generated by the solar tiles to an edge of the textile substrate.
